(19) United States
(12) Patent Application Publication
(10) Pub. No.: US 2006/0256973 A1
(43) Pub. Date: Nov. 16, 2006

(54) Method and apparatus for correlation and mobile playback of bird songs and animals calls

(76) Inventors: Eric Kirsten, Burlington, CT (US); Tracey Kirsten, Burlington, CT (US); Gregory Leibold, Littleton, CO (US)

Correspondence Address: EDWARDS & ANGELL, LLP, P.O. BOX 55874, BOSTON, MA, 02205, US

(21) Appl. No.: 11/405,790

(22) Filed: Apr. 18, 2006

Related U.S. Application Data
(60) Provisional application No. 60/672,380, filed on Apr. 19, 2005.

(51) Int. Cl. H03G 3/00

(52) U.S. Cl. 381/61

(57) ABSTRACT

A method and apparatus for portably playing animal calls after scanning a text object from a record medium. In one embodiment, the present invention includes: an optical scanner; electronic storage system to store sound files of recorded animal calls; a processor, programmed to recognize text objects and correlate them to the stored sound files; an audio output system; and a hand-holdable housing.

### CROSS-REFERENCE TO RELATED APPLICATION

This application claims the benefit of U.S. Provisional Application No. 60/672,380, which was filed Apr. 19, 2005, the contents of which are incorporated herein by reference.

### BACKGROUND OF THE INVENTION

There is a rapidly growing segment of the worldwide population that has discovered bird watching (“birding”). A hobby that has been around since at least the early 19^{th} century, it is one that requires very little equipment on the part of the “birder” and also, very few limitations on locale or climate. In short, birding can be enjoyed anywhere by anyone.

A typical birder will utilize two primary tools while birding in the field: A pair of binoculars and a bird field guide. The binoculars are obviously used to better see a bird that is flying or singing at the top of a tall tree, etc. The field guide is used by the birder (even the advanced birder) to help identify a bird when seen. The guide will typically include a drawing(s) of each separate species of bird, a short paragraph describing the bird's habitat, typical behavior and major identifying markings for that bird, a map showing the bird's chosen habitat for different seasons throughout the year, and even a written description of the bird's song (for example, “cheery cheery cheerio”). Thus, the typical birder will see a bird and either immediately identify it by sight, or as is often the case, narrow it down to a family (i.e., finch, warbler, or flycatcher, for example) and use the field guide to get to the final identification.

However, the advanced birder (those who typically lead birding trips) will often take advantage of their ability to identify a bird's song or call when identifying a bird, rather than simply the markings that are visible to the eye. This offers a tremendous advantage to the advanced birder because of the common situation of a bird being too far away or too high to be seen. In thick, deciduous forests, it is often very difficult to locate a singing bird by sight, but a birder's ability to know that bird's song or call will make identifying that bird much simpler.

An advanced birder typically develops their knowledge of bird calls through a long process of memorization. There are many CD's and tape cassettes on the market that offer a complete audio library of bird songs and calls. While it is not practical to use these tools in the field to help identify a bird “on the fly”, they are typically used as study tools. A birder spends countless hours studying these calls until the knowledge is such that can be usable in the field, where it really matters.

There is a demand among the “typical” birder to be able to identify a bird (or narrow down the choice) in the field, utilizing only that bird's song or call. Birders are handicapped by only using their eyes because, in a sense, bird watching is as much about listening as it is about watching. Similarly, other nature lovers would benefit from being able to quickly play other animals' calls when attempting to identify or observe an animal in the field.

### SUMMARY OF THE INVENTION

In one aspect, the invention generally features a method and an apparatus for portably playing animal calls after scanning a text object from a record medium. The present invention includes: an optical scanner; electronic storage system to store sound files of recorded animal calls; a processor, programmed to recognize text objects and correlate them to the stored sound files; an audio output system; and a hand-holdable housing.

In one aspect, the invention features optical scanning technology to allow the user simply to scan a text object and after scanning the text object, the present invention forms an association between the scanned text and an internally stored database of animal calls, such that when the text is linked to the appropriate call, the call is played on a small, integrated speaker. The whole process is nearly immediate and transparent to the user. In one embodiment, the text object is the name of a bird as it is written in a field guide next to the bird's picture, and the animal call is the bird call associated with that text.

In other embodiments, the present invention may include: a peripheral connector to allow reprogramming or replacement of the stored animal call files or animal names; a display to graphically indicate the animal calls being played or other information; a jack for headphones or other external speakers; function keys to permit alternate animal calls (such as mating calls) to be played or to allow certain songs to be replayed; a microphone to record live animal calls in the field for immediate comparison; automatic shutoff feature after period of nonuse; and a keyboard or other function keys to allow the user to type a bird's name to choose an animal call without scanning. The present invention may also include a “next-best-guess” function button, whereby the animal calls would be grouped by similarity. If a user scans an animal name that he believes is correct but the replayed animal call is not what he is hearing in the field, the next-best-guess function key would replay the next most similar call from the animal-call library until the user finds the correct call.

Other objects and further scope of the present invention will become apparent from a detailed description hereinafter. It should be understood, however, that the detailed description and specific examples, while indicating particular embodiments of the invention, are given by way of example and not limitation. Various changes and modifications within the spirit and scope of the invention will be apparent to those skilled in the art.

The present invention will be more fully understood from the detailed description given below and the accompanying drawings, which are provided by way of illustration only and are not limiting to the invention described herein.

### BRIEF DESCRIPTION OF THE DRAWINGS

FIGS. 1A-1C are schematic diagrams showing the portable animal-call player according to one embodiment of the present invention. FIG. 1A is a top view of the embodiment. FIG. 1B is a side view of the embodiment shown in FIG. 1A. FIG. 1C is a bottom view of the embodiment shown in FIG. 1A.

FIG. 2A is an exploded view of the embodiment shown in FIGS. 1A through 1C. FIG. 2B is a bottom view of the circuit board shown in FIG. 2A.

FIG. 3 is a block diagram illustrating the logical components of the animal call player in FIGS. 1a through 1c and FIGS. 2A and 2b.

FIG. 4 is a flow chart illustrating one embodiment of the method of the present invention.

FIG. 5 is a flow chart illustrating another embodiment of the method of the present invention.

### DETAILED DESCRIPTION OF THE INVENTION

The invention generally features an apparatus and related method for portably playing animal calls after scanning a text object from a record medium.

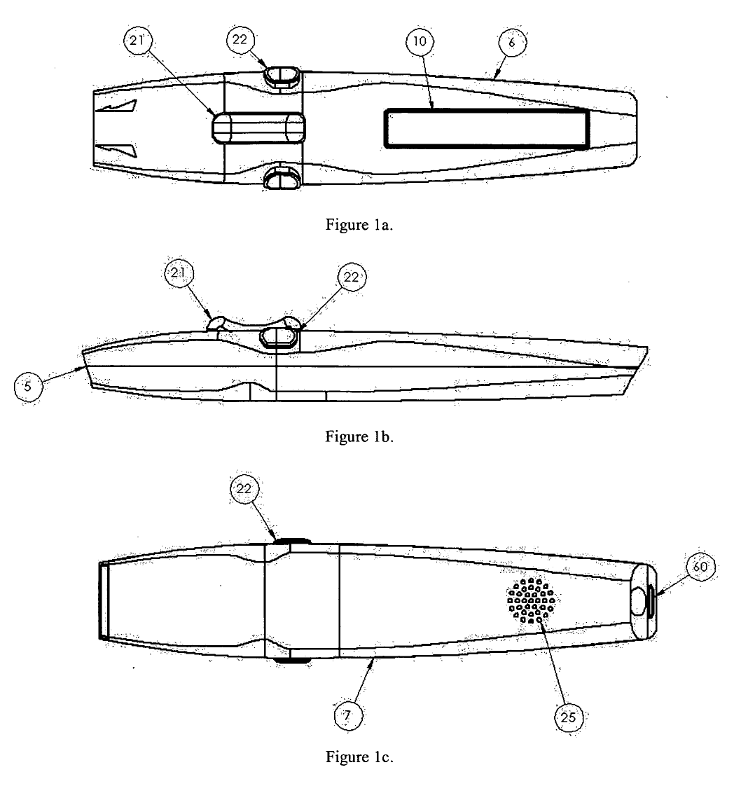

In the embodiment illustrated in FIGS. 1a through 1c, the animal-call player 1 includes housing 5 to house the components of the player 1. In this embodiment, housing 5 is comprised of an upper housing 6 and lower housing 7 that fit together to form housing 5, and housing 5 is made of plastic or other lightweight material to make the player 1 more portable for field use. Because the intended for use in the field in a variety of weather conditions, in this embodiment the housing 5 is of a material and made to such tolerances that it will make the player 1 as a whole essentially waterproof. Although the present invention can take a variety of sizes and shapes, to increase portability, in one embodiment the housing 5 is approximately the size and shape of a highlighter (5-7 inches in length). In addition, in this embodiment all components of the player 1 be contained within the housing 5 (as opposed to having separate or external components) to maximize portability and usability in the field.

The housing 5 includes an aperture to accommodate a display screen 10. Display 10 may be an LCD screen or other means for displaying electronic text and graphics and may include an integrated back light for viewing in low light. Player 1 also includes function keys 20, which may include a rocker button 21 and other function buttons 22. Rocker button 21 is a bi-directional selection device as is known in the art that can be used in conjunction with the display 10 to allow the user to select text or functions as may be provided by the present invention. Player 1 may also include other function buttons 22 to permit the user to perform certain actions as further described herein.

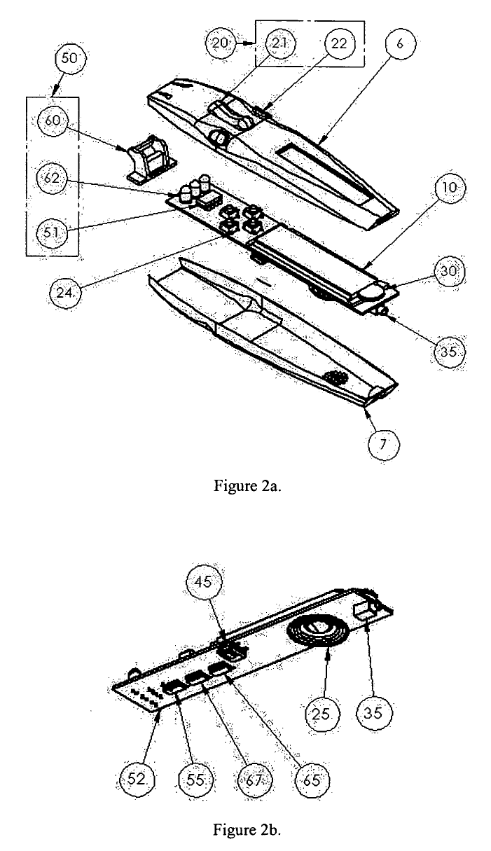

FIG. 2a is an exploded version of the embodiment shown in FIGS. 1a through 1c. In one embodiment, the player 1 also includes a speaker 25 for audibly playing sound files as set forth herein. The speaker 25 is of high quality to permit the user to appreciate the subtle differences among bird songs and also waterproof to permit the use of player 1 in all types of weather conditions. Player 1 may also include a volume control 30 and audio jack 35 to permit the user to listen to sound files via headphones or other speakers for better acoustics or more privacy. Audio jack 35 could also serve as a jack for connection to stationary, external speakers for at-home practice at recognizing bird songs.

Player 1 may also include a microphone 40 to record and use animal calls in the field as taught herein. A peripheral connector 45, such as a USB connector, may also be included to permit the user to connect the player 1 to an external computing device, such as a PC. Player 1 is preferably powered by a battery power source (not pictured) that may be rechargeable. Player 1 may also include an automatic shutoff feature after a set period of nonuse.

Within the housing 5, the player 1 includes optical scanner 50. Optical scanner 50 can take any of a number of forms known in the art. For example, U.S. Pat. No. 6,270,013 (Lipman et al.) (“Lipman Patent”) teaches the use of a scanner head including a roller, a CCD array, a character detection system, a displacement detector system, a record media detection system, a focusing lens, dual light sources, and lens mirror. The Lipman Patent is incorporated by reference herein as a nonexclusive example of the optical scanner 50 utilized by the present invention. The Lipman Patent generally teaches an apparatus for recognizing printed text and associating that printed text to a stored file. In the case of the Lipman Patent, the printed text is associated with a file of an equivalent word in a different language.

Another example of optical scanner 50 is taught in U.S. Pat. No. 4,393,460 (Masuzawa et al.) (“Masuzawa Patent”). The Masuzawa Patent teaches a device for reading text, associating the text to translated word(s) in a different language, and then outputting either text to a display or a translation to a speaker. The Masuzawa Patent is incorporated by reference herein as a nonexclusive example of the optical scanner 50 utilized by the present invention.

The present invention can make use of any optical scanner 50 known in the art. In one embodiment, optical scanner 50 is capable of recognizing a variety of fonts and native text in animal field guides rather than requiring specific text objects correlating to a particular species. In this manner, the player 1 can be used in conjunction with any existing field guides rather than requiring printed guides to include specific or proprietary text objects just to enable the operation of player 1.

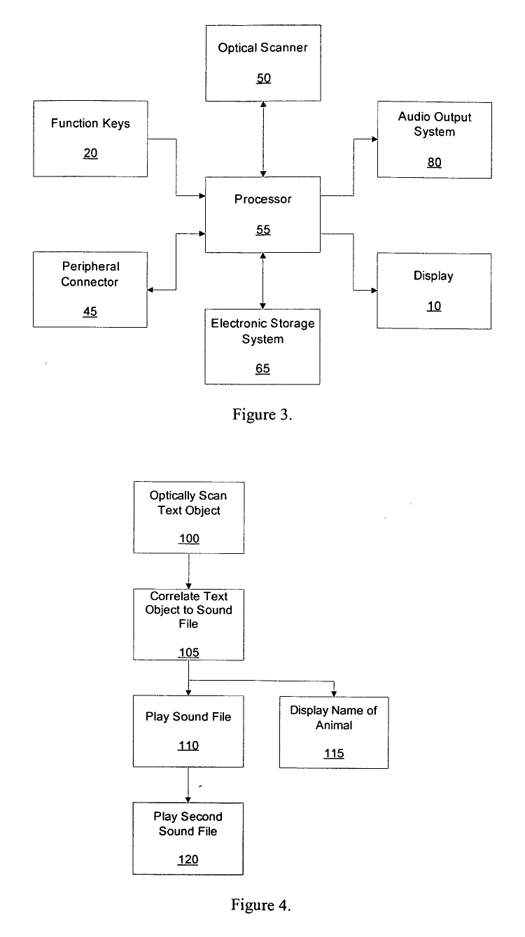

In the embodiment shown in FIGS. 2a and 2b, certain components are connected to a printed circuit board (PCB) 52. FIG. 2a includes a top view of the PCB 52 and components, and FIG. 2b is a bottom view of the PCB 52 and additional components. FIG. 3 is a representation of the logical components of one embodiment of the present invention.

Referring now to FIGS. 2a and 2b and FIG. 3, processor 55 controls the functions of the player 1. Processor 55 can be any processor known in the art, including ARM processors such as the Amtel AT91SAM7 series. In one embodiment, the optical scanner 50 includes a scanning tip 60 that the user passes over a text object, such as the name of a particular bird in a birding field guide. The scanning tip 60 includes a lens assembly to that works in conjunction with light emitting diodes (LEDs) 62 and linear sensor array 51 to capture the image of a text object. In this embodiment, the optical scanner 50 includes scanning tip 60, LEDs 62, and linear sensor array 51. LEDs 62 may also act as an emergency flashlight and should be bright enough to adequately illuminate the record medium, even in low light. The optical scanner 50 then sends the scanned image of the text object to the processor 55. Player 1 also includes an electronic storage system 65 for storing a library of animal calls and corresponding to text objects, such as animal names, recognized by the optical scanner 50. Storage system 65 may include Flash memory or PROM or any other type of nonvolatile memory and may also include RAM to be used in ordinary operation of processor 55. As used herein, animal calls can refer to any sound made by an animal that is sufficient to help identify the animal.

In one embodiment, the storage system 65 is reprogrammable via peripheral connector 45. For example if a user has a separate library of bird songs that he/she wishes to use, it can substitute that library for the one already on the storage system 65 by transferring such alternate library to the storage system 65 from his/her PC. In one embodiment, the nonvolatile memory in storage system 65 appears to the processor and external PC like any other disk drive or memory stick. This can be accomplished using the FAT12 or FAT16 standard file systems, though other workable file systems will be apparent to those of skill in the art. The nonvolatile portion of storage system 65 can also be removable to permit more flexibility. For example, a user may utilize a flash memory portion of storage system 65 that includes all of the songs of North American song birds but then substitute a separate flash memory for a library of the songs of South American song birds when on a trip to South America. Using flash memory as part of storage system 65 may also be helpful in manufacturing because a manufacturer need not anticipate how many players 1 of each type (North America, South America, etc.)—the files can be loaded to meet specific orders.

While processor 55, storage system 65, and optical scanner 50 are shown as separate logical blocks in FIG. 2, it will be appreciated by those of skill in the art that some of these components could be combined into a single processor unit. Sound files representing bird songs may be stored in the storage system 65 in Mp3 format or other electronic sound file formats.

Processor 55 includes inputs from the buttons 22 and rocker button 21 (collectively, function keys 20), and microphone 40. Function keys 20 work by way of switches 24, which are opened and closed by operation of function keys 20 and are operably connected to processor 55 via digital input/output lines on PCB 52 to digital input bits on processor 55. Processor 55 also includes output connections to the speaker 25, display 10, and audio jack 35. In one embodiment, processor 55 is connected to the speaker 25 and audio jack 35 through a decoder 67, such as an Mp3 decoder, to decode the digital signal sent by the processor 55 into an analog signal for play by speaker 25 or through audio jack 35. In one embodiment, the speaker 25, audio jack 35, and decoder 67 together comprise an audio output system. In other embodiments, the audio output system can comprise any of these components individually, or grouped differently, or any other components sufficient to enable the audible playing of a sound file.

In one embodiment of the invention, a user operates the player 1 as follows. The user runs the scanning tip 60 over a text object in a record medium, such as the name of a bird printed in a birding field guide. The processor 55 turns on LEDs 62 to illuminate the record medium. The optical scanner 50 then senses the text object via linear sensor array 51 and captures an image of the text object. The optical scanner 50 preferably includes an analog-to-digital converter and sends a digital signal to the processor 55 representing the text object. The processor 55 then identifies the text object and makes a call to the storage system 65. The storage system 65 returns to the processor 55 a sound file that has been correlated to the text object—such as the sound file representing a bird song of the bird represented by the text object. The processor 55 then sends the sound file to the audio output system 80, where the bird song is played so that the user can hear the bird song of the bird represented by the text object. Audio output system 80 may include a speaker 25, audio jack 35, digital-to-analog decoder and any other circuitry necessary to enable the user to hear the played animal call or to connect the player 1 to an external speaker.

Because the names of animals in field guides are often several words in length, depending on the optical scanner 50 employed, it may be necessary to have a function key 20 that the user depresses during the scanning process. The user then depresses the designated function button 20 prior to scanning the text object(s) and releases the function button when the scan of the full text object(s) is completed, thereby signaling to the processor 55 that the scan is completed.

As used herein, text objects may include the names of birds or other animals, pictures, or symbols in a record medium.

In other embodiments, when the processor 55 makes a call to the storage system 65, storage system 65 returns both the sound file corresponding to the text object but also a stored text representation of the text object. In this embodiment, the processor 55 sends the sound file to the speaker 25 and the text representation to the display 10. If scanning confidence is high enough, the normalized image of the text object from the record medium can be sent directly to display 10. For example, when the user scans the name of a bird in a field guide, the player 1 plays the bird's song over the speaker 25 and displays the bird's name on the display 10 so that the user can confirm that the correct bird song is being played.

In another embodiment, one of the function keys 20, is designated as the mating call key. For example, in the case of birds, most birds have a regular song and a separate song that they use as a mating call. In this embodiment, when a text object representing a particular bird is scanned while the mating call key is depressed, the processor 55 requests a corresponding sound file from the storage system 65. In this embodiment, the storage system 65 includes a library of mating call sound files in addition to the typical bird song files. The mating call for the selected bird is then played via speaker 25. Alternatively, instead of a mating-call function button, the processor 55 is programmed to recognize a bird name that has been scanned in backwards (e.g., right to left in an English language book), thereby signaling that the user wishes to play the mating call of that bird rather than the regular song for that bird. In still another embodiment, if the mating-call function key after a regular song for a bird has been played, the mating call for that same bird this then played.

In another embodiment, the user has the option to use the display 10 and rocker button 21 to scroll through the names of all birds whose songs are stored in the storage system 65. When a bird's name is selected via the rocker button 21, the processor 55 then makes the appropriate call to the storage system 65 and sends the sound file for that bird's song to the speaker 25.

In another embodiment, after the user plays a sound file that turns out not to be a match with the natural call he/she is hearing in the field, he/she has the option to push another function button 20 to play the “next best guess.” The processor 55 then calls the storage system 65 to return the sound file of the bird song that is most like the song just played. The name of the bird whose song is then being played is displayed so that the user can see what the next-best-guess of the player 1 is. This can be accomplished by creating groupings within storage system 65 of similar animal calls so that each time the next best guess function button 20 is depressed, the storage system 65 returns the sound file for the next song in that group until the correct song is played. For example, all finches could be logically grouped in storage system 65 so that if a user incorrectly guesses that a bird he is observing is a particular finch, the next-best-guess function would allow him to play the songs of all the other finches until finding the right call.

Groupings could be accomplished during the manufacturing/programming process by creating a relational database and linking each animal by its physical characteristics and/or by the acoustic similarities of its call. Any characteristics could be used to group animals. For example, small, predominantly red birds with a high-pitched call could be a group. That way, if a user could see a bird well enough to know that it is small and red, but guessed wrong by initially scanning the name of another small, red bird from his/her field guide, the player 1 could start playing the calls of other birds in that group. By displaying the names on display 10 of each successive bird whose call is played, the use will know how to look up the bird in his or her field guide when the correct call is finally played.

Processor 55 could also be programmed to accept information from the user in the field through function keys 20 to narrow the search. For example, the storage system 65 could be programmed with physical characteristics of each animal, such as, e.g.: relative size, color, song pitch, and plumage in the case of birds. The user could have the option to enter as much of this information as he or she has been able to gather from observing the animal in the field. If the user scans the name of the animal he believes he is observing, but the call played does not match what he is hearing, processor 55 could send a list of other birds with the physical characteristics entered to display 10, and the user can select the names via function keys 20 to play those calls until finding the call matching what he is hearing in the field. Alternatively, if the user has no initial guess, the processor 55 could send such a list of bird names to display 10 even without a scan being performed.

Or, in another embodiment, the processor 55 can be programmed to compare the acoustic profiles of each of the sound files stored in the storage system 65. In this embodiment, when the next-best-guess function button 20 is depressed, the processor 55 calls the sound file in the storage system 65 that has the most similar acoustic profile to the sound file that was most recently called. This can be accomplished, for example, by using the methods and apparatus described in U.S. Patent Application No. 20040107104, filed Dec. 3, 2002, to compare the acoustic profiles of the last call played by the player 1 to the other sound files stored in the storage system 65.

In another embodiment, a function key 20 is designated as a replay button. The replay function button 20, when depressed, would cause the processor 55 to replay the last sound file played. Alternatively, the display 10 could display a list of the most recently played animal calls for quick selection via function keys 20 and playback.

In another embodiment, the user can select a quiz mode, whereby the processor 55 would randomly call from storage system 65 and play sound files of animal calls. After hearing the call played, the user would then need to scan the correct animal name from his/her field guide in order to be alerted that the answer was correct. Alternatively, after an animal call is randomly played, and plurality of animal names are displayed on display 10 and the user must choose from one of the displayed names via the rocker button 21.

FIG. 4 is a flow-chart illustrating one embodiment of the method of the present invention. This method comprises: optically scanning a text object representing a first animal 100; correlating the text object to a sound file of the call of the first animal 105; playing the sound file 110; displaying the name of the animal 115; and playing a second sound file 120.

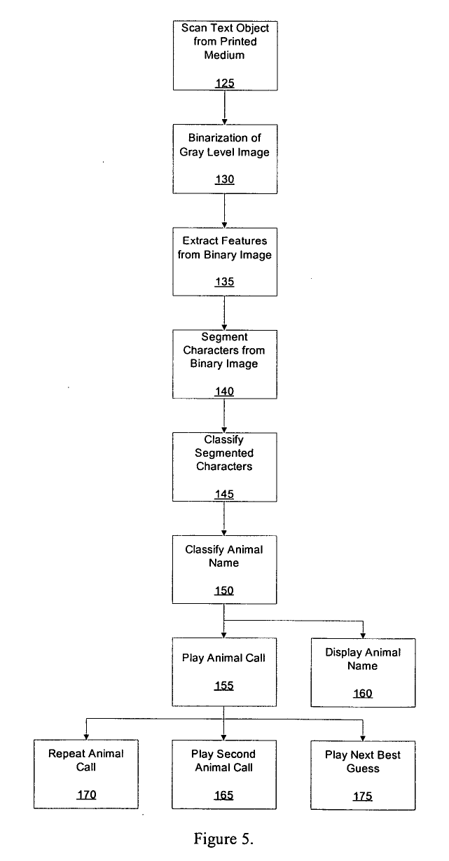

FIG. 5 is a flow-chart illustrating another embodiment of the method of the present invention. The user scans 125 a text object from a record medium, such as a field guide, by running scanning tip 60 across the words on the page. In one embodiment, the scan is initiated by the user pressing a function key 20 and ended by the user releasing the function key 20. The linear sensor array 51, in conjunction with LEDs 62 and scanning tip 60, capture a gray level image of the text object. The scanning window provided in scanning tip 60 may be sized appropriately to accommodate the expected height of the text object to ensure adequate image capture of the text object while limiting inadvertently capturing extraneous text on the recorded medium.

In addition, in one embodiment, the linear sensor array 51 may provide for exposure adjustment to improve performance in varying light conditions. Such exposure adjustment may be controlled automatically by a servo loop mechanism that depends on image quality. The TAOS TSL3301 linear sensor array is one type of linear sensor array that provides for automatic exposure adjustment.

The gray level image is provided to the processor 55, which binarizes 130 the gray level image into a binary image. In one embodiment, this occurs by measuring the average darkness of the linear samples and labeling samples that are significantly darker than average as text and those significantly lighter than average as background. Some sophisticated binarization algorithms delay binarization until all gray scale linear scans have been recompiled; however, memory restrictions in some embodiments of the present invention may require early binarization, before buffering multiple linear samples into an image.

As linear samples are binarized, they are stored in an input buffer that is part of the storage system 65. When a full scan has been completed, the binarization step 130 also compensates for black-on-white or white-on-black lettering. For example, the processor may count the number of black versus white pixels and deem the majority color to be the background and convert those pixels to 0's while converting the remaining pixels to be 1's.

The feature extraction step 135 involves improving the compiled image by various methods known in the art. For example, in one embodiment, the image is refactored to compensate for scan angle (skew) correction. The image is then cropped to eliminate extraneous information. For example, during a typical scan there may be some columns that are recorded before the scanning tip 60 comes in contact with the record medium. There may also be a time period after the end of the text object when the scan is still taking place. These extraneous areas can be removed from the image by the processor 55 examining the columns of the compiled image to look for several columns of unchanging data, which will be considered the left-side of the text object (in a left-to-right scan) and, after the text object, another series of columns of unchanging data, which will be considered the end of the scan. Similarly, the top and bottom of the compiled image can be examined to eliminate extraneous data above or below the text object that might otherwise make character recognition difficult.

Next, the processor 55 segments 140 the characters in the image. In an embodiment where the text object is the printed name of an animal, this involves separating the individual letters of the word in the image. In one embodiment, the processor is programmed to take advantage of the projection analysis approach, as discussed by Casey and Lecolinet in “A Survey of Methods and Strategies in Character Segmentation,” IEEE Transactions on Pattern Analysis and Machine Intelligence, Volume 18, No. 7, July 1996 (page 5). In one embodiment, this involves: ANDing each column of bits in the compiled image with the previous column; counting the number of foreground bits in each column and placing them in an array; taking the derivative of the array by calculating the difference between each entry and the previous entry; taking the derivative again; defining the gap between characters; and normalizing the height and width of each character.

The processor 55 then classifies 145 the segmented characters. In one embodiment, this involves determining the probable font of the text object and then comparing the normalized, segmented characters from the image to font table characters stored in storage system 65. Storage system 65 may include a library of supported fonts in one or multiple languages/alphabets. The library of supported font character images can be compiled and stored by saving in a font size intentionally larger than the actual font that will be scanned by player 1. This allows for more accuracy when the font characters are reduced in size to match the scanned-in characters as part of this character classification step 145. Each input character in the image is compared to the font library to compute the probability that the text string is written in a particular, supported font. Once the most-probable font is determined, each character is classified as one of the characters in that font by comparing the normalized input character in the image to the font library character at the pixel level.

The processor then classifies 150 the text object as a particular animal name based on the stored library of text objects in the storage system 65. The closest animal name in the stored library of text object may be used even if there is no exact match. For example, if the character classification step 145 resolved the characters in a particular scan to be “B-l-a-c-k T-a-c-k-c-d W-o-o-d-p-c-c-k-c-r,” the processor could classify the text object as a Black Backed Woodpecker because that was the closest match in the stored library. In one embodiment, the decoded characters are compared to the words in the stored library using the concept of edit distance, also called Levenshtein Distance, invented by Vladimir Levenshtein in 1965. In addition, the processor could use the optical scanning confidence data generated from the pixel comparison during character classification step 145 to weight the edit distance algorithm.

Once the processor 55 classifies the text object as an animal name, a corresponding sound file of an animal call is played 155 either through speaker 25 or other means for playing the sound file (such as audio jack 35). In some embodiments, the name of the animal may also be displayed 160 on display 10. In addition, upon pressing appropriate function keys 20, the user can: play a second animal call 165 (such as a mating call); repeat the last-played animal call 170; or play 175 the “next-best guess” of player 1 in the manner previously described herein.

### OTHER EMBODIMENTS

From the foregoing description, it will be apparent that variations and modifications may be made to the invention described herein to adopt it to various usages and conditions. Such embodiments are also within the scope of the following claims.

The recitation of a listing of elements in any definition of a variable herein includes definitions of that variable as any single element or combination (or subcombination) of listed elements. The recitation of an embodiment herein includes that embodiment as any single embodiment or in combination with any other embodiments or portions thereof.

All patents and publications mentioned in this specification are herein incorporated by reference to the same extent as if each independent patent and publication was specifically and individually indicated to be incorporated by reference.

We claim:

1. An animal-call player, comprising:
an optical scanner capable of scanning text objects from a record medium;
electronic storage system to store sound files of recorded animal calls, including at least a first sound file from a first animal;
a processor, operatively connected to the optical scanner and the electronic storage system, programmed to recognize a first said text object scanned by the optical scanner and correlate the first said text object to at least the first said sound file;
an audio output system, operatively connected to the processor, for playing the first said sound file when the first said text object is recognized by said processor; and
a hand-holdable housing to house at least the optical scanner, the electronic storage system, and the processor.

2. The animal-call player of claim 1, wherein:
the first text object is a printed representation of the name of said first animal.

3. The animal-call player of claim 1, further comprising:
a function key, operatively connected to the processor, wherein when said function key is activated, the processor causes a second sound file from said sound files stored in the electronic storage system to be played by the audio output system.

4. The animal-call player of claim 3, wherein:
the second sound file is a recorded animal call from the same species as the first animal.

5. The animal-call player of claim 3, wherein:
the second sound file is a recorded animal call from a second animal that is of a different species from the first animal.

6. The animal-call player of claim 5, wherein:
the call of the second animal is similar to the call of the first animal.

7. The animal-call player of claim 1, further comprising:
a function key, electronically connected to the processor, wherein when said function key is activated, the processor causes the first sound file to be replayed by the audio output system.

8. The animal-call player of claim 1, further comprising:
a peripheral connector for operatively connecting the processor to a separate device to reprogram the processor.

9. The animal-call player of claim 1, further comprising:
a peripheral connector for operatively connecting the electronic storage system to a separate device to reprogram the electronic storage system.

10. The animal-call player of claim 1, further comprising:
a display, operatively connected to the processor, for displaying the name of the first animal.

11. The animal-call player of claim 10, wherein the display also displays the names of animals whose calls have previously been played.

12. The animal-call player of claim 11, further comprising:
a first function key for selecting one of the displayed names; and
a second function key for causing the processor to play one of said sound files correlated to said one of the displayed names.

13. The animal-call player of claim 5, wherein the function key permits a user of the animal-call player to enter at least one physical characteristic of the first animal and wherein the second animal shares said at least one physical characteristic.

14. An animal-call player, comprising:
means for optically scanning text objects from a record medium;
means for electronically storing sound files of recorded animal calls;
means, operatively connected to said means for scanning and said means for storing, for correlating a first said text object to at least a first said sound file;
means, operatively connected to said means for correlating, for playing the first said sound file; and
means for housing at least the means for optically scanning, the means for electronically storing, and the means for correlating in a single hand-holdable housing.

15. The animal-call player of claim 14, wherein the first said text object is a printed representation of the name of the first animal.

16. The animal-call player of claim 14, further comprising:
means for displaying the name of the first animal.

17. The animal-call player of claim 14, further comprising:
means for causing the first sound file to be replayed.

18. A method for playing animal calls, comprising the steps of:
optically scanning a human-readable text object representing a first animal;
correlating said text object to at least a first sound file of a recorded call by said first animal; and
audibly playing said first sound file.

19. The method for playing animal calls of claim 18, further comprising the step of:
displaying the name of the first animal while audibly playing the first sound file.

20. The method for playing animal calls of claim 19, further comprising the step of:
audibly playing a second sound file of a recorded call by a second animal.
